(19) United States
(12) Patent Application Publication
(10) Pub. No.: US 2019/0227376 A1
(43) Pub. Date: Jul. 25, 2019

(54) POLARIZING PLATE AND METHOD OF MANUFACTURING LIQUID CRYSTAL DISPLAY PANEL

(71) Applicant: SHENZHEN CHINA STAR OPTOELECTRONICS TECHNOLOGY CO., LTD., GUANGDONG (CN)

(72) Inventors: Zhenxia CHEN, GUANGDONG (CN); Lixuan CHEN, GUANGDONG (CN)

(21) Appl. No.: 15/761,433

(22) PCT Filed: Mar. 5, 2018
(86) PCT No.: PCT/CN2018/077967

§ 371 Date: Mar. 20, 2018

(30) Foreign Application Priority Data
Jan. 25, 2018 (CN) 201810072179.X

(51) Int. Cl. G02F 1/1335; G02B 5/30; H01L 27/12; B32B 7/12; B32B 27/36; B32B 23/04

(52) U.S. Cl. CPC G02F 1/133528; G02F 1/133514; G02B 5/3025; B32B 17/064; B32B 7/12; B32B 27/36; B32B 23/04; H01L 27/1218

(57) ABSTRACT

A polarizing plate is laminated onto a surface of a substrate, for converting the light passing through the substrate into a polarized light. The polarizing plate includes a polarizing layer provided with a laminating adhesive on a side of the polarizing layer, being laminated to the substrate by the laminating adhesive. A removable adhesive is disposed on a side of the polarizing layer opposite to the laminating adhesive, and is removable by an adjustment of an environmental temperature for lamination. A protective layer is laminated to the polarizing layer through the removable adhesive so as to support and protect the polarizing layer.

### CROSS REFERENCE TO RELATED APPLICATIONS

This application is a U.S. National Phase application submitted under 35 U.S.C. § 371 of Patent Cooperation Treaty Application serial No. PCT/CN2018/077967, filed Mar. 5, 2018, which claims the priority of China Patent Application serial No. 201810072179.X, filed Jan. 25, 2018, the disclosures of which are incorporated herein by reference in their entirety.

### BACKGROUND OF INVENTION

### 1. Field of Invention

The present invention relates to a display technology field, and more particularly to a polarizing plate and a method of manufacturing a liquid crystal display panel having the polarizing plate.

### 2. Related Art

With development of technology and prosperity of society, people rely on exchange and delivery of information that increases daily. Display devices are a major and fundamental tool for presenting images of the exchange and delivery of information, and is now becoming a popular research subject that researchers in the photoelectric field are scrambling for. Polarizing components play a major part in thin film transistor-liquid crystal display (TFT-LCD) panels. LCDs cannot present a perfect image without the polarizing components. Additionally, the polarizing components, in a high degree, are regarded as key in determining important features of the LCD, such as, penetration rate, brightness, or thickness, and so on.

During development of the LCD, and with application of quantum dots (QDs) in the LCD, ultra-thin LCDs, specific LCDs used in critical environments, and soft displays, requirements of built-in polarizing plates are increased rapidly and turning to be a problem to be solved today. However, conventional polarizing plates are made up of pressed multilayer films, have a thickness greater than 200 um, and are also known to have poor moist heat resistance properties. Thus, they are not capable of meeting new generation of displaying requirements.

As described above, conventional polarizing plates have the drawbacks of greater thickness, poor property of moist heat resistance, and are not beneficial to achieve display devices of lightweight and compact size and to extend lifespan of the display devices.

### SUMMARY OF INVENTION

Accordingly, an object of the present invention is to provide a polarizing plate having the features of a small thickness and great performance of moist heat resistance, so as to achieve a display device of lightweight and compact size as well as longer lifespan, and thereby overcoming the technical problems of conventional polarizing plates that have greater and thicker size and poor property of moist heat resistance, and are not beneficial to achieve display devices of lightweight and compact size and a longer lifespan.

To achieve the above object, a polarizing plate of the present invention is laminated onto a surface of a substrate, for converting the light passing through the substrate into a polarized light.

The polarizing plate of the present invention comprises a polarizing layer provided with a laminating adhesive on a side thereof, the polarizing layer laminated to the substrate by the laminating adhesive, a dye polarizing film being adopted as the polarizing layer; a removable adhesive which is disposed on a side of the polarizing layer opposite to the laminating adhesive, and is removable by adjusting an environmental temperature for lamination; and a protective layer laminated to the polarizing layer through the removable adhesive so as to support and protect the polarizing layer; wherein after lamination of the polarizing layer onto the substrate is completed, the environmental temperature for lamination is adjustable to enable removal of the protective layer in conjunction with the removable adhesive, thereby to reduce thickness of the polarizing plate.

In one aspect of the present invention, the protective layer is made of polyethylene terephthalate film material.

In another aspect of the present invention, the protective layer is made of triacetyl cellulose ester film material.

In another aspect of the present invention, a side of the protective layer far away from the polarizing layer is provided with a supporting layer, which is laminated onto the protective layer by the laminating adhesive.

In another aspect of the present invention, the supporting layer is made of triacetyl cellulose ester film material.

The present invention comprises a polarizing plate in accordance with another embodiment, which is laminated onto a surface of a substrate, for converting the light passing through the substrate into a polarized light. The polarizing plate comprises a polarizing layer provided with a laminating adhesive on a side thereof, the polarizing layer laminated to the substrate with the laminating adhesive; a removable adhesive which is disposed on a side of the polarizing layer opposite to the laminating adhesive, and is removable by adjusting an environmental temperature for lamination; and a protective layer laminated to the polarizing layer through the removable adhesive so as to support and protect the polarizing layer; wherein after lamination of the polarizing layer onto the substrate is completed, the environmental temperature for lamination is adjustable to enable removal of the protective layer in conjunction with the removable adhesive, thereby to reduce a thickness of the polarizing plate.

In one aspect of the present invention, the protective layer is made of Polyethylene Terephthalate film material.

In another aspect of the present invention, the protective layer is made of three cellulose acetate film material.

In another aspect of the present invention, a side of the protective layer far away from the polarizing layer is provided with a supporting layer, which is laminated to the protective layer with the laminating adhesive.

In another aspect of the present invention, the supporting layer is made of three cellulose acetate film material.

In accordance with above objects of the present invention, the present invention comprises a method of manufacturing a liquid crystal display panel having the polarizing plate as described above. The method comprises steps of:

S10, providing a first glass substrate, then placing a lower polarizing plate on the first glass substrate, and next arranging a thin film transistor array on the lower polarizing plate in order to form an array substrate;

S20, providing a second glass substrate, then placing an upper polarizing plate on the second glass substrate, and next placing a color resist layer on the upper polarizing plate in order to form a color film substrate; and

S30, placing the first glass substrate corresponding to a side of the upper polarizing plate, and placing the second glass substrate corresponding to a side of the lower polarizing plate, such that the first glass substrate is disposed opposite to the second glass substrate, and then assembling the array substrate and the color film substrate into a box; wherein S10 further comprises:

S101, aligning and laminating a polarizing layer of the lower polarizing plate onto the first glass substrate;

S102, adjusting the environmental temperature for lamination so as to render an adhering effectiveness of a removable adhesive of the lower polarizing plate ineffective;

S103, removing the protective layer and the removable adhesive and keeping the lower polarizing layer in place, thereby completing the lamination of the lower polarizing plate onto the first glass substrate; and wherein S20 further comprises:

S201, aligning and laminating a polarizing layer of the upper polarizing plate onto the second glass substrate;

S202, adjusting the environmental temperature for lamination so as to render an adhering effectiveness of a removable adhesive of the upper polarizing plate ineffective; and

S203, removing the protective layer and the removable layer to remain the lower polarizing layer, thereby completing the lamination of the upper polarizing plate and the second glass substrate.

In one aspect of the present invention, the polarizing layers of the upper polarizing plate and the lower polarizing plate are both made of a dye polarizing film.

In another aspect of the present invention, the protective layers of the lower polarizing plate and the upper polarizing plate are both made of polyethylene terephthalate film material.

In another aspect of the present invention, the protective layers of the lower polarizing plate and the upper polarizing plate are both made of triacetyl cellulose ester film material.

The advantageous effects of the present invention are as follows: the polarizing plate of the present invention utilizes the dye polarizing film having a greater property of moist heat resistance as the polarizing layer, and economize the use of multiple film layers capable of providing protection, thereby to reduce the thickness of the polarizing plate as well as the entire thickness of the liquid crystal display panel, and is advantageous to fulfill the requirements for a display device being lightweight and compact and having the better property of moist heat resistance, and thereby to improve the display quality and extend life span of the display device.

### BRIEF DESCRIPTION OF DRAWINGS

FIG. 1 is a schematic structural view of a polarizing plate the present invention;

FIG. 2 is another schematic structural view of a polarizing plate the present invention;

FIG. 3 is another schematic structural view of a polarizing plate the present invention;

FIG. 4 is a flow chart of a method of manufacturing a liquid crystal display panel having the polarizing plate of the present invention; and

FIG. 5 is a schematic structural view of the liquid crystal display panel manufactured by the method of FIG. 4.

### DESCRIPTION OF PREFERRED EMBODIMENTS

The following embodiments are referring to the accompanying drawings for exemplifying specific implementable embodiments of the present disclosure. Furthermore, directional terms described by the present disclosure, such as upper, lower, front, back, left, right, inner, outer, side, etc., are only directions by referring to the accompanying drawings, and thus the used directional terms are used to describe and understand the present disclosure, but the present disclosure is not limited thereto. In the drawings, elements with similar structures are labeled with like reference numerals.

Referring to FIG. 1, the present invention provides a polarizing plate comprising a polarizing layer 101 made of a dye polarizing film. The dye polarizing film has better heat-resistance and light-resistance properties compared with a polarizing plate manufactured by conventional methods which utilize raw iodine as dichroic material.

A removable adhesive 103 is disposed on a side of the polarizing layer 101 opposite to the laminating adhesive 102. The removable adhesive 103 is a temperature-dependent adhesive and is removable by adjusting environmental temperature for lamination in such a way that an adhesive effectiveness of the removable adhesive 103 turns to be ineffective. For instance, the removable adhesive 103 is exemplified by a low temperature removable adhesive, which is capable of being rendered ineffective after use in a low temperature environment for a predetermined period. Alternatively, the removable adhesive 103 is exemplified by a high temperature removable adhesive, which is capable of being rendered ineffective after use in a high temperature environment for a predetermined period.

A protective layer 104 is laminated to the polarizing layer 101 through the removable adhesive 103, so as to support and protect the polarizing layer 101. The protective layer 104 is provided not only for protecting the polarizing layer 101 from being physically or chemically damaged, but also for increasing a thickness of the polarizing layer 101, thereby to improve tenacity of polarizing layer 101. Under the support of the protective layer 104, the process of lamination of the polarizing layer 101 onto a surface of a substrate is not likely to cause air bubbles therebetween. Even though there are a very small number of air bubbles occurring, they can be de-formed by means of heating and compressing. Preferably, the protective layer 104 is made up of two or more than two protective layers laminated together, the multiple protective layers are laminated by the laminating adhesive 102, to enhance support for the polarizing layer 101 and reduce the number of air bubbles and wrinkles.

In an embodiment of manufacturing the polarizing plate, the polarizing layer 101, the removable adhesive 103, and the protective layer 104 can be laminated in a manner of one-time lamination. Specifically, a surface of the protective layer 104 is firstly coated with the removable adhesive 103, then the polarizing layer 101 is laminated onto a surface of the removable adhesive 103, and finally a surface of the polarizing layer 101 is coated with the laminating adhesive 102.

In another embodiment of manufacturing the polarizing plate, the polarizing layer 101, the removable adhesive 103, and the protective layer 104 can be laminated in a manner of two-time lamination. First, the protective layer 104 is laminated to the removable adhesive 103, along with adjustment of compressing and heating processes during the period of lamination to ensure that the protective layer 104 is perfectly laminated to the removable adhesive 103; second, a multilayer formed by the protective layer 104 and the removable adhesive 103 is laminated to the polarizing layer 101, along with adjustment of compressing and heating processes during the period of lamination to reduce viscosity of the removable adhesive 103, so that the protective layer 104 in conjunction with the removable adhesive 103 are enabled to be removed in a later removal process.

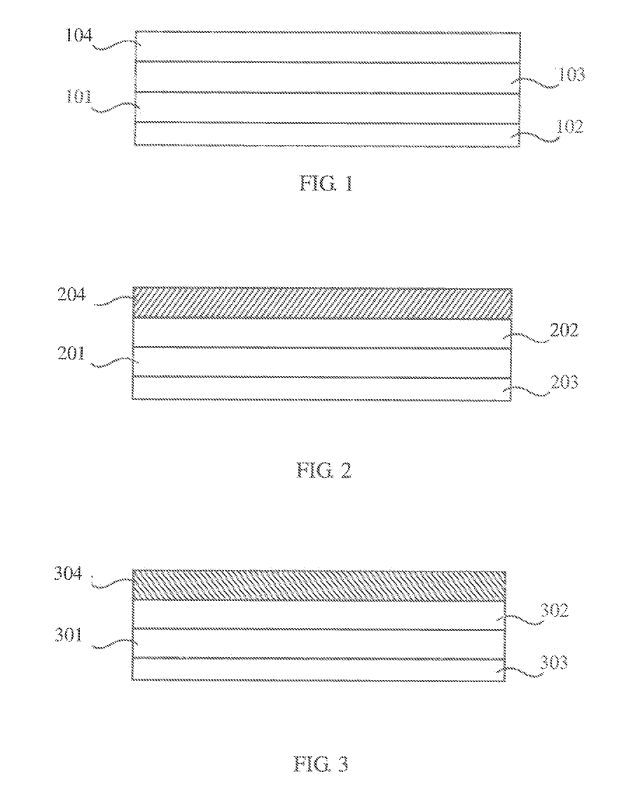

As shown in FIG. 2, the polarizing plate of the present invention comprises a polarizing layer 201, a removable adhesive 202, and a protective layer 204.

The polarizing layer 201 is provided with a laminating adhesive 203 on a side thereof. The polarizing layer 201 is laminated to the substrate by the laminating adhesive 203. The removable adhesive 202 is disposed on a side of the polarizing layer 201 opposite to the laminating adhesive 203, and is removable by an adjustment of an environmental temperature for lamination. The protective layer 204 is laminated to the polarizing layer 201 through the removable adhesive 202 so as to support and protect the polarizing layer 201.

After lamination of the polarizing layer 201 onto the substrate is completed, the environmental temperature for lamination is adjustable to enable removal of the protective layer 204 in conjunction with the removable adhesive 202, thereby to reduce thickness of the polarizing plate.

The protective layer 204 is made of polyethylene terephthalate film material, which has a lower water penetration rate and is capable of preventing the polarizing layer 201 from being penetrated by water vapor in a process of manufacturing a liquid crystal display panel and thereby affecting polarizing performance.

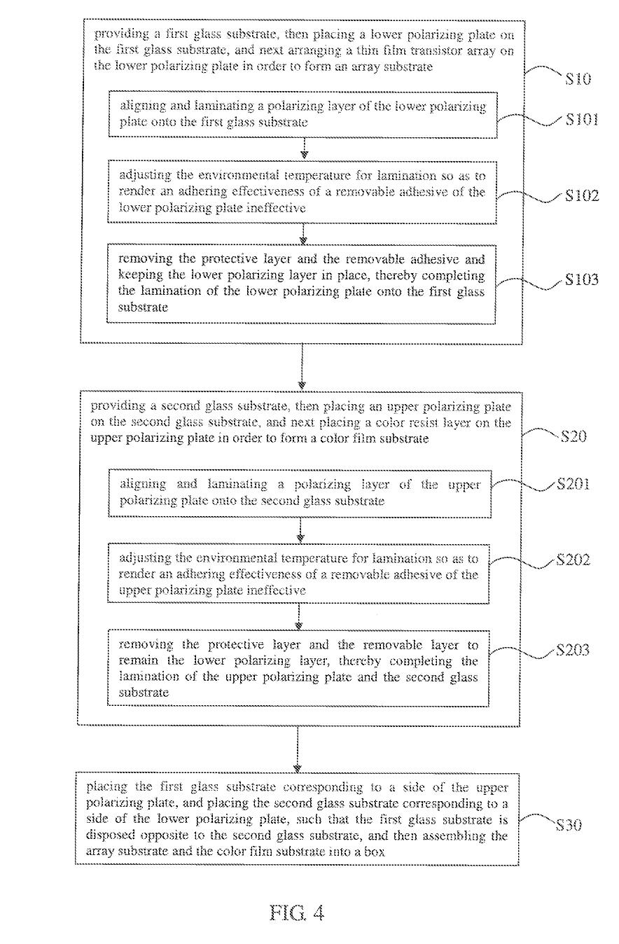

As shown in FIG. 3, the polarizing plate of the present invention comprises a polarizing layer 301, a removable adhesive 302, and a protective layer 304.

The polarizing layer 301 is provided with a laminating adhesive 303 on a side thereof. The polarizing layer 301 is laminated to the substrate by the laminating adhesive 303. The removable adhesive 302 is disposed on a side of the polarizing layer 301 opposite to the laminating adhesive 303, and is removable by adjusting environmental temperature for lamination. The protective layer 304 is laminated to the polarizing layer 301 through the removable adhesive 302 to support and protect the polarizing layer 301.

The protective layer 304 is made of triacetyl cellulose ester film material, which has better tenacity and is capable of preventing air bubbles and wrinkles from occurring in a process of lamination of the polarizing layer 301 onto the substrate.

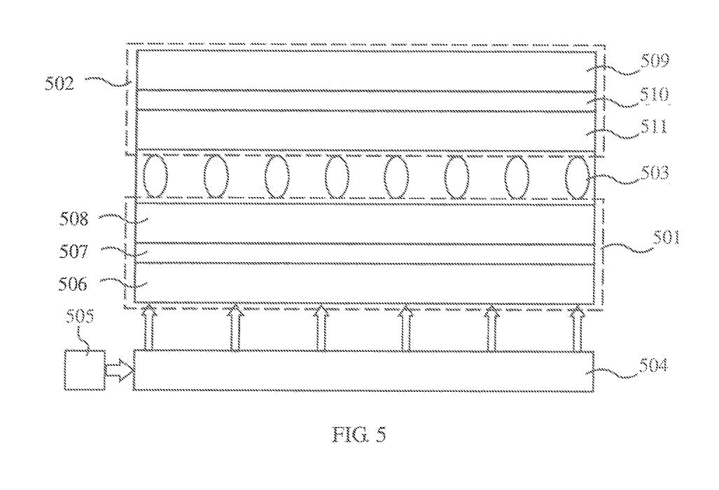

To achieve the above-mentioned objects, the present invention comprises a method of manufacturing a liquid crystal display panel having the polarizing plate as described above. As shown in FIG. 4, the method comprises steps of:

S10, providing a first glass substrate, then placing a lower polarizing plate on the first glass substrate, and next arranging a thin film transistor array on the lower polarizing plate in order to form an array substrate.

S20, providing a second glass substrate, then placing an upper polarizing plate on the second glass substrate, and next placing a color resist layer on the upper polarizing plate in order to form a color film substrate.

S30, placing the first glass substrate corresponding to a side of the upper polarizing plate, and placing the second glass substrate corresponding to a side of the lower polarizing plate, such that the first glass substrate is disposed opposite to the second glass substrate, and then assembling the array substrate and the color film substrate into a box.

The step of S10 further comprise S101, aligning and laminating a polarizing layer of the lower polarizing plate onto the first glass substrate; S102, adjusting the environmental temperature for lamination so as to render an adhering effectiveness of a removable adhesive of the lower polarizing plate ineffective; and S103, removing the protective layer and the removable adhesive and keeping the lower polarizing layer in place, thereby completing the lamination of the lower polarizing plate onto the first glass substrate.

The step of S20 further comprise S201, aligning and laminating a polarizing layer of the upper polarizing plate onto the second glass substrate; S202, adjusting the environmental temperature for lamination so as to render an adhering effectiveness of a removable adhesive of the upper polarizing plate ineffective; and S203, removing the protective layer and the removable layer to remain the lower polarizing layer, thereby completing the lamination of the upper polarizing plate and the second glass substrate.

As shown in FIG. 5, the liquid crystal display panel manufactured by the method of the present invention comprises an array substrate 501 and a color film substrate 502 both disposed corresponding to each other. A liquid crystal layer 503 is disposed in between the array substrate 501 and the color film substrate 502. A bottom portion of the color film substrate 502 is provided with a backlight module. The backlight module comprises a light guiding plate 504 and a light source 505 disposed on an incident side edge of the light guiding plate 504.

The array substrate 501 comprises a first glass substrate 506. A lower polarizing plate 507 is disposed on the first glass substrate 506. A thin film transistor array 508 is disposed on the lower polarizing plate 507.

The color film substrate 502 comprises a second glass substrate 509. An upper polarizing plate 510 is disposed on the second glass substrate 509. A color resist layer 511 is disposed on the upper polarizing plate 510.

The first glass substrate 506 is disposed corresponding to a side of the upper polarizing plate 510. The second glass substrate 509 is disposed corresponding to a side of the lower polarizing plate 507, such that the first glass substrate 506 is disposed opposite to the second glass substrate 509.

The upper polarizing plate 510 and the lower polarizing plate 507 are placed inside the liquid crystal display panel. In the event that an environmental temperature is rising, the polarizing plate having no supporting film attached thereto is not capable of being wrapped because no supporting film is to be heated. In addition, a dye polarizing film has a better property of heat-resistance than that of a conventional iodine-based polarizing film, and thereby is not easily to be affected to be rendered ineffective. Furthermore, a cross section of the polarizing film of the present invention is disposed and protected in a plastic frame, to prevent the polarizing performance of the polarizing film from being adversely affected by absorbing moisture.

The advantageous effects of the present invention are as follows: the polarizing plate of the present invention utilizes the dye polarizing film having a greater property of moist heat resistance as the polarizing layer, and economizes the use of multiple film layers capable of providing protection, thereby to reduce the thickness of the polarizing plate as well as the entire thickness of the liquid crystal display panel, and is advantageous to fulfill the requirements for a display device being lightweight and compact and having the better property of moist heat resistance, and thereby to improve the display quality and extend life span of the display device.

It is understood that the invention may be embodied in other forms within the scope of the claims. Thus the present examples and embodiments are to be considered in all respects as illustrative, and not restrictive, of the invention defined by the claims.

1. A polarizing plate, laminated onto a surface of a substrate, for converting light passing through the substrate into polarized light, the polarizing plate comprising:
a polarizing layer provided with a laminating adhesive on a side thereof, the polarizing layer laminated to the substrate by the laminating adhesive, a dye polarizing film being adopted as the polarizing layer;
a removable adhesive disposed on a side of the polarizing layer opposite to the laminating adhesive, and is removable by adjusting an environmental temperature for lamination; and
a protective layer laminated to the polarizing layer through the removable adhesive, to support and protect the polarizing layer;
wherein after lamination of the polarizing layer onto the substrate is completed, the environmental temperature for lamination is adjustable to enable removal of the protective layer in conjunction with the removable adhesive, thereby to reduce thickness of the polarizing plate.

2. The polarizing plate of claim 1, wherein the protective layer is made of polyethylene terephthalate film material.

3. The polarizing plate of claim 1, wherein the protective layer is made of triacetyl cellulose ester film material.

4. The polarizing plate of claim 1, wherein a side of the protective layer far away from the polarizing layer is provided with a supporting layer, which is laminated onto the protective layer by the laminating adhesive.

5. The polarizing plate of claim 4, wherein the supporting layer is made of triacetyl cellulose ester film material.

6. A polarizing plate, laminated onto a surface of a substrate, for converting light passing through the substrate into polarized light, the polarizing plate comprising:
a polarizing layer provided with a laminating adhesive on a side thereof, the polarizing layer laminated to the substrate with the laminating adhesive;
a removable adhesive disposed on a side of the polarizing layer opposite to the laminating adhesive, and is removable by adjusting an environmental temperature for lamination; and
a protective layer laminated to the polarizing layer through the removable adhesive so as to support and protect the polarizing layer;
wherein after lamination of the polarizing layer onto the substrate is completed, the environmental temperature for lamination is adjustable to enable removal of the protective layer in conjunction with the removable adhesive, thereby to reduce a thickness of the polarizing plate.

7. The polarizing plate of claim 6, wherein the protective layer is made of polyethylene terephthalate film material.

8. The polarizing plate of claim 6, wherein the protective layer is made of three cellulose acetate film material.

9. The polarizing plate of claim 1, wherein a side of the protective layer far away from the polarizing layer is provided with a supporting layer, which is laminated to the protective layer with the laminating adhesive.

10. The polarizing plate of claim 9, wherein the supporting layer is made of three cellulose acetate film material.

11. A method of manufacturing a liquid crystal display panel having the polarizing plate of claim 6, the method comprising steps of:
S10, providing a first glass substrate, placing a lower polarizing plate on the first glass substrate, and arranging a thin film transistor array on the lower polarizing plate in order to form an array substrate;
S20, providing a second glass substrate, placing an upper polarizing plate on the second glass substrate, and placing a color resist layer on the upper polarizing plate in order to form a color film substrate; and
S30, placing the first glass substrate corresponding to a side of the upper polarizing plate, and placing the second glass substrate corresponding to a side of the lower polarizing plate, such that the first glass substrate is disposed opposite to the second glass substrate, and assembling the array substrate and the color film substrate into a box;
wherein S10 further comprises:
S101, aligning and laminating a polarizing layer of the lower polarizing plate onto the first glass substrate;
S102, adjusting an environmental temperature for lamination so as to render an adhering effectiveness of a removable adhesive of the lower polarizing plate ineffective;
S103, removing the protective layer and the removable adhesive and keeping the lower polarizing layer in place, thereby completing the lamination of the lower polarizing plate onto the first glass substrate; and
wherein S20 further comprises:
S201, aligning and laminating a polarizing layer of the upper polarizing plate onto the second glass substrate;
S202, adjusting the environmental temperature for lamination so as to render an adhering effectiveness of a removable adhesive of the upper polarizing plate ineffective; and
S203, removing the protective layer and the removable layer to remain the lower polarizing layer, thereby completing the lamination of the upper polarizing plate and the second glass substrate.

12. The method of claim 11, wherein the polarizing layers of the upper polarizing plate and the lower polarizing plate are both made of a dye polarizing film.

13. The method of claim 12, wherein the protective layers of the lower polarizing plate and the upper polarizing plate are both made of polyethylene terephthalate film material.

14. The method of claim 12, wherein the protective layers of the lower polarizing plate and the upper polarizing plate are both made of triacetyl cellulose ester film material.
